(19) United States
(12) Patent Application Publication
(10) Pub. No.: US 2012/0262310 A1
(43) Pub. Date: Oct. 18, 2012

(54) INPUT DEVICE

(75) Inventors: YUNG-HAN HSIAO, Tu-Cheng (TW); YEN-CHI TSAI, Tu-Cheng (TW); HAO-CHUN CHEN, Tu-Cheng (TW)

(73) Assignee: HON HAI PRECISION INDUSTRY CO., LTD., Tu-Cheng (TW)

(21) Appl. No.: 13/367,488

(22) Filed: Feb. 7, 2012

(30) Foreign Application Priority Data
Apr. 12, 2011 (TW) 100112712

(51) Int. Cl. H03M 11/00

(52) U.S. Cl. 341/22

(57) ABSTRACT

An input device includes a keyboard and a touch module. The keyboard includes two keyboard connectors. Each of the two keyboard connectors is located at two opposite sides of the keyboard. The touch module includes a module connector. The module connector is connected to any one of the two keyboard connectors. The touch module is electronically coupled to the keyboard.

### BACKGROUND

1. Technical Field

The present disclosure relates to input devices, and more particularly to an input device with a keyboard.

2. Description of Related Art

A keyboard may be provided with a touch pad for a computer system for inputting characters, symbols, or numerals. The touch pad is typically integrated with the keyboard. The position of the touch pad is unchanged relative to the keyboard, which is inconvenient when the position thereof should be adjusted. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an input device in accordance with an embodiment.

FIGS. 2-5 are different assembled views of the input device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

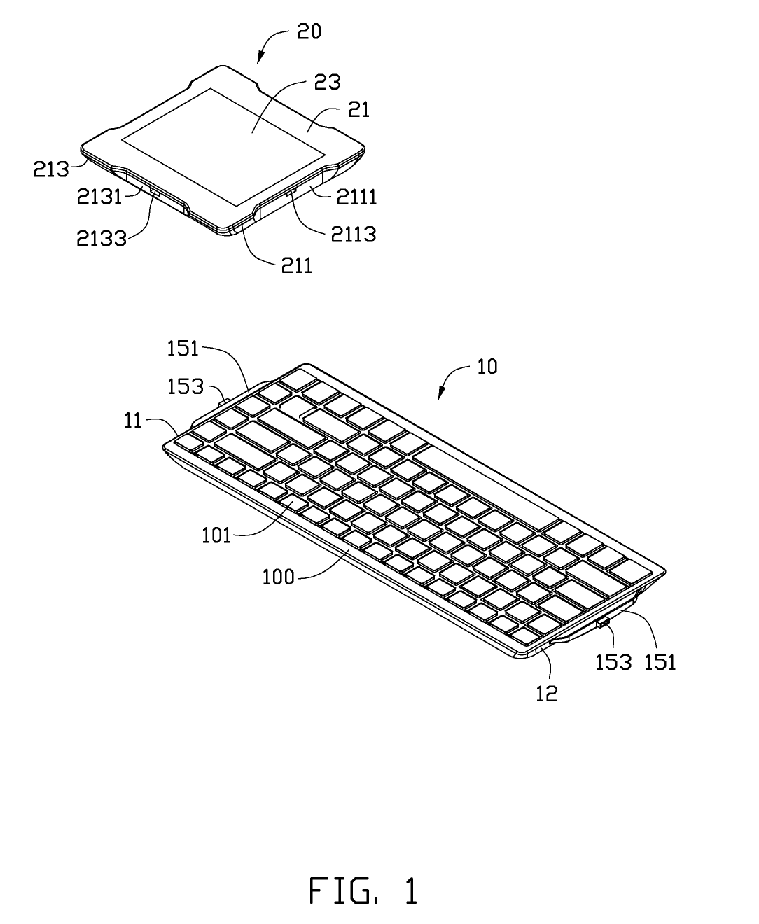

Referring to FIG. 1, an input device in accordance with an embodiment includes a keyboard 10 and a touch module 20 separated from the keyboard 10.

The keyboard 10 includes a keyboard body 100. A plurality of keys 101 are located on the keyboard body 100. A plurality of characters are engraved or printed on the keys 101. The keyboard 10 can send a signal to an electronic device, such as a computer, when one of the plurality of keys 101 is pressed. The keyboard 10 further includes a first keyboard side 11 and a second keyboard side 12 opposite to the first keyboard side 11. A keyboard connector 153 is located on each of the first keyboard side 11 and the second keyboard side 12. In one embodiment, a convex portion 151 extends from each of the first keyboard side 11 and the second keyboard side 12.

The touch module 20 includes a touch module body 21 and a touch pad 23 located on a top surface of the touch module body 21. The touch module 20 is capable of sending a control signal to the electronic device when the touch pad 23 is touched. The touch module body 21 includes two first body side body walls 211 and two second body sidewalls 213. The two first body sidewalls 211 are opposite to each other on opposite sides of the touch module body 21, and the two second body sidewalls 213 are opposite to each other on opposite sides of the touch module body 21. A first module connector 2113 is defined in each of the two first body sidewalls 211, and a second module connector 2133 is defined in each of the two second body sidewalls 213. The first module connector 2113 and the second module connector 2133 are shaped to engage with the keyboard connector 153. In an embodiment, a first recess 2111 is defined in each of the two first body sidewalls 211, a second recess 2131 is defined in each of the two second body sidewalls 213, and the first recess 2111 and the second recess 2131 are shaped to receive the keyboard connector 153. In another embodiment, the first module connector 2113 and the second module connector 2133 are ports.

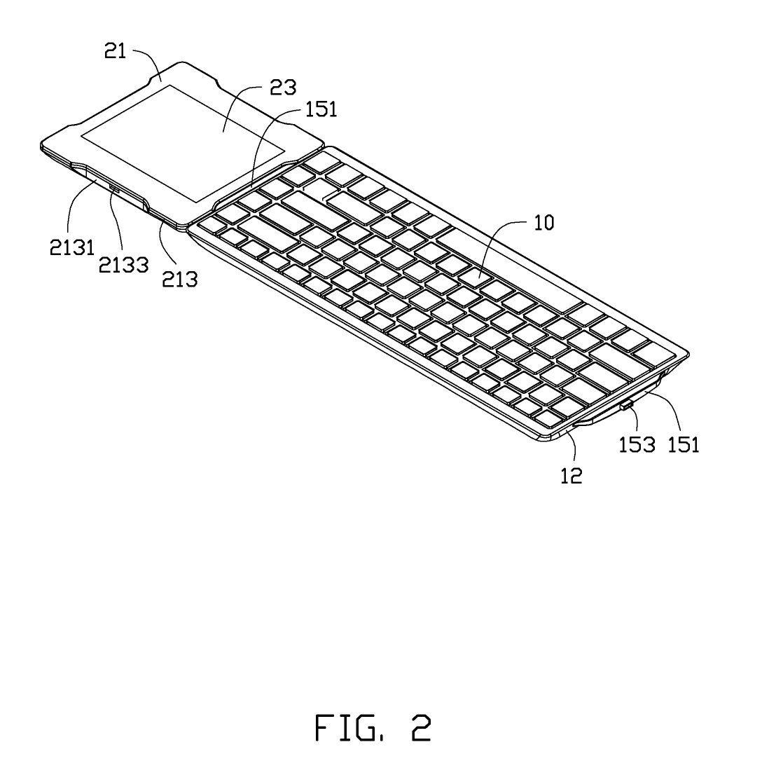

Referring to FIG. 2, the touch module 20 is located on the first keyboard side 11 of the keyboard 10. The first module connector 2113 of one first body sidewall 211 is engaged with the keyboard connector 153 of the first keyboard side 11, and the touch module 20 is electronically connected to the keyboard 10. In one embodiment, the convex portion 151 is received in the first recess 2111 of the one first body sidewall 211.

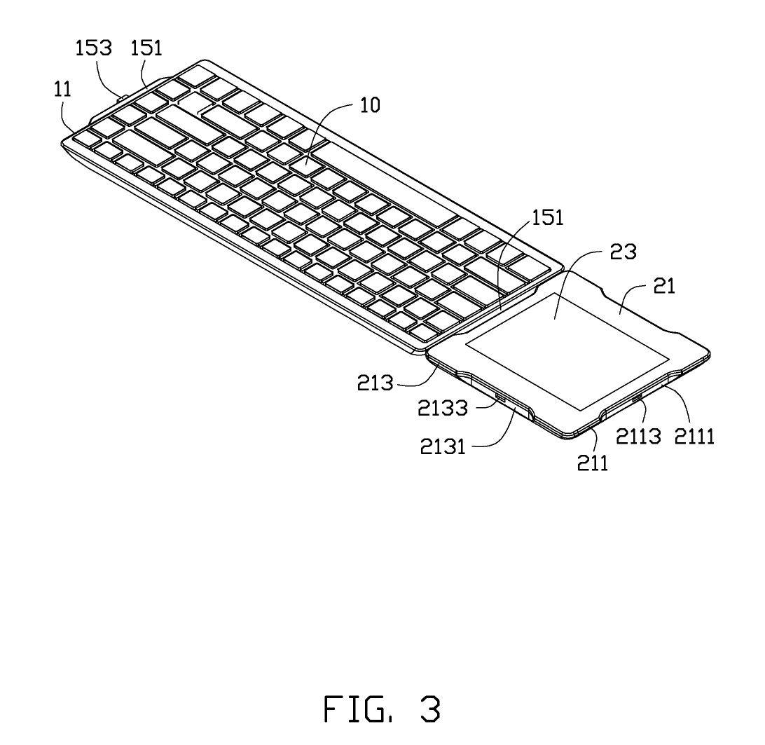

Referring to FIG. 3, the touch module 20 is located on the second keyboard side 12 of the keyboard 10. The first module connector 2113 of one first body sidewall 211 is engaged with the keyboard connector 153 of the second keyboard side 12, and the touch module 20 is electronically connected to the keyboard 10. The convex portion 151 is received in the first recess 2111 of the one first body sidewall 211.

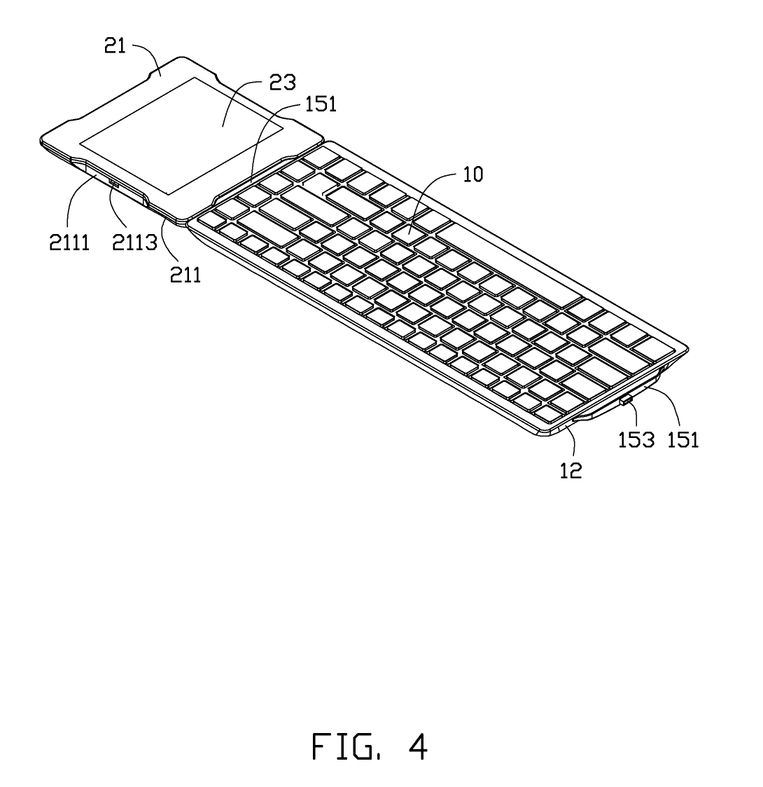

Referring to FIG. 4, the touch module 20 is located on the first keyboard side 11, the second module connector 2133 of one second body sidewall 213 is engaged with the keyboard connector 153 of the first keyboard side 11, and the touch module 20 is electronically connected to the keyboard 10. The convex portion 151 is received in the second recess 2131 of the one second body sidewall 213.

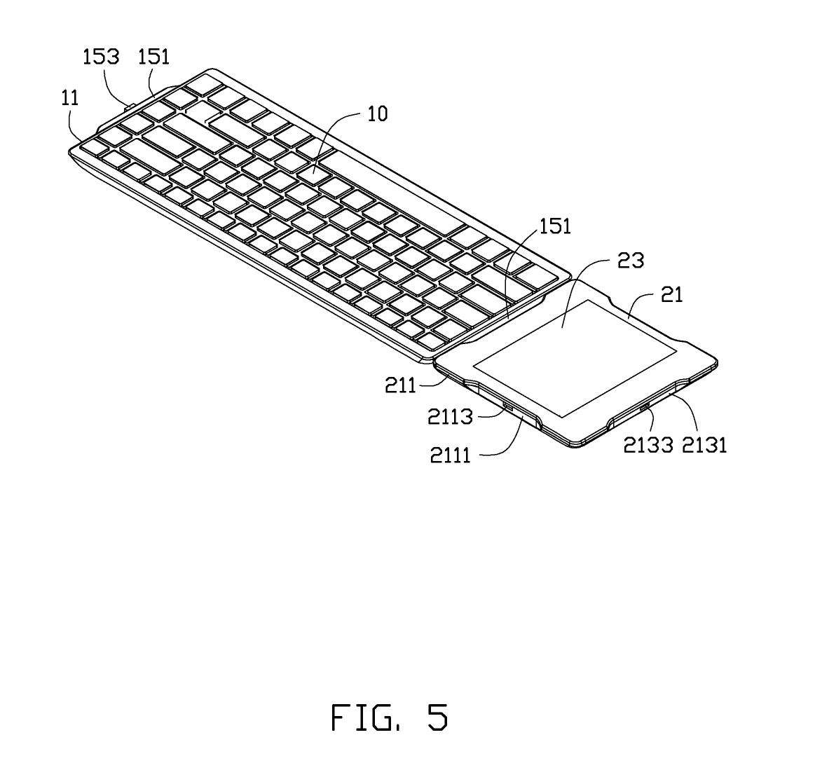

Referring to FIG. 5, the touch module 20 is located on the second keyboard side 12, the second module connector 2133 of one first body sidewall 213 is engaged with the keyboard connector 153 of the second keyboard side 12, and the touch module 20 is electronically connected to the keyboard 10. The convex portion 151 is received in the second recess 2131 of the one second body sidewall 213.

In one embodiment, the touch module 20 and the touch pad 23 are substantially rectangular.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An input device comprising:
a keyboard comprising a keyboard body, the keyboard body comprising two opposite sides;
two keyboard connectors, each of the keyboard connector disposed at each of the two opposite sides of the keyboard body;
a touch module; and
a module connector connected to one of the two keyboard connectors, wherein the touch module is electronically coupled to the keyboard via the module connector.

2. The input device of claim 1, wherein the keyboard further comprises a convex portion extending from the each of the two opposite sides of the keyboard body, and the touch module defines a recess shaped to receive the convex portion.

3. The input device of claim 2, wherein the keyboard connector is located on the convex portion, and the module connector is located in the recess.

4. The input device of claim 1, wherein the touch module comprises a touch module body, the touch module body comprises two first body sidewalls opposite to each other and two second body sidewalls opposite to each other, each of the two first body sidewalls is connected to the two second body sidewalls, and the module connector is located on one of the two first body sidewalls or the two second body sidewalls.

5. The input device of claim 4, wherein the touch module further comprises a touch pad located on the body.

6. The input device of claim 5, wherein the touch module body and the touch pad are substantially rectangular.

7. The input device of claim 1, wherein the module connector is a USB port, and the each of the two keyboard connectors is a USB connector.

8. An input device comprising:
a keyboard comprising a keyboard body, the keyboard body comprising a first keyboard side and a second keyboard side opposite to the first keyboard side;
two keyboard connectors, each of the two keyboard connectors is located on each of the first keyboard side and the second keyboard side;
a touch module comprising a touch module body, the touch module body comprising two first body sidewalls and two second body sidewalls, the two first body sidewalls being at two opposite sides of the touch module body, the two second body sidewalls being at another two opposite sides of the touch module body, one of the two first body sidewalls connected to the two second body sidewalls, a first module connector located on each of the two first body sidewalls, and a second module connector located on each of the two second body sidewalls;
wherein one of the first module connectors and the second module connectors is engaged with any one of the keyboard connectors, and the touch module is electronically coupled to the keyboard.

9. The input device of claim 8, wherein the keyboard further comprises a convex portion extending from the each of the first keyboard side and the second keyboard side, each of the two first body sidewalls and the two second body sidewalls defines a recess shaped to receive the convex portion.

10. The input device of claim 9, wherein the keyboard connectors are located on the convex portions, and the first module connector and the second module connector are located in the recesses.

11. The input device of claim 8, wherein the touch module further comprises a touch pad located on the touch module body.

12. The input device of claim 11, wherein the touch module and the touch pad are substantially rectangular.

13. The input device of claim 8, wherein the first module connector and the second module connector are USB ports, and the keyboard connectors are USB connectors.
